(19) United States
(12) Patent Application Publication
(10) Pub. No.: US 2010/0022037 A1
(43) Pub. Date: Jan. 28, 2010

(54) METHOD FOR FABRICATING CMOS IMAGE SENSOR

(76) Inventor: In-Bae Cho, Yeoju-gun (KR)

Correspondence Address: SHERR & VAUGHN, PLLC, 620 HERNDON PARKWAY, SUITE 320, HERNDON, VA, 20170, US

(21) Appl. No.: 12/506,699

(22) Filed: Jul. 21, 2009

(30) Foreign Application Priority Data
Jul. 23, 2008 (KR) 10-2008-0071575

(51) Int. Cl. H01L 31/18; H01L 21/66

(52) U.S. Cl. 438/16; 438/59; 257/E21.53; 257/E31.121; 257/E31.11

(57) ABSTRACT

A method for fabricating a CMOS image sensor includes developing a semiconductor substrate provided with metal pads with tetramethylammonium hydroxide (TMAH), to etch the metal pads. In accordance with the method, it is possible to realize normal output of materials, which were previously scrapped due to problems including pad corrosion, appearance defects and bonding pad issues which may occur in the process of fabricating CMOS image sensors. As a result, advantageously, it is possible to reduce wafer scrap and improve product yield.

The present application claims priority under 35 U.S.C. 119 to Korean Patent Application No. 10-2008-0071575 (filed on Jul. 23, 2008), which is hereby incorporated by reference in its entirety.

### BACKGROUND

Image sensors are semiconductor devices which convert optical images into electrical signals. Image sensors may be broadly classified into charge coupled device (CCD) image sensors and complementary metal oxide silicon (CMOS) image sensors.

CMOS image sensors are semiconductor devices which convert optical images into electrical signals by a CMOS technique, and which utilize a switching mode to detect electrical signals using the desired number of transistors present in unit pixels.

A CMOS image sensor may be fabricated by sequentially forming metal pads, color filter arrays, planarized layers and microlenses. Aluminum (Al) pads used as metal pads for the fabrication of the CMOS image sensor disadvantageously corrode.

The most representative corrosion occurring on CMOS image sensor products is flower-like corrosion caused by fluorine (F). In this regard, fluorine (F) which remains on the pad surface reacts with the Al pads to produce (AlF₆)₃⁻, as represented by Formula I below:

Al+6F⁻ [symbol] (AlF₆)₃⁻+3e− (I)

In addition, the (AlF₆)₃⁻ serves as an anode (oxidation), which reacts with O₂, N₂ or H₂O to produce a novel corrosive substance, as represented by Formula II below:

O₂+2H₂O+4e⁻ [symbol] 4OH⁻

N₂+8H₂O+6e [symbol] 2(NH₄)⁺+8OH⁻ (II)

The products thus obtained are OH— and NH₄+, which produce Al(OH)₃ and (NH₄)₃(AlF₆), respectively, to promote corrosion, as represented by Formula III below:

4Al+8OH⁻+2(NH₄)⁺ [symbol] 3Al(OH)₃+α

(AlF₆)3⁻+3(NH₄)⁺ [symbol] (NH₄)3(AlF₆) (III)

The aluminum (Al) pad corrosion in the process of fabricating CMOS image sensors disadvantageously causes deterioration in bonding strength of semiconductor devices upon fabrication. This affects operation properties and reliability of the devices. In particular, serious aluminum (Al) pad corrosion negatively affects bonding pads, making it impossible to perform electrical signal in-out tests on products, and necessitating that the products be scrapped due to appearance defects.

In the related process for fabricating CMOS image sensors, corrosion of Al pads and thus occurrence of pits cause deterioration in reliability and yield. Accordingly, there is no rework method for materials when Al pads corrode. For this reason, all of the corroded materials are scrapped. Thus, the most important issue in CMOS image sensors is a method for reducing the fluorine concentration in the pad surfaces.

### SUMMARY

Embodiments relate to a method for fabricating a CMOS image sensor. More specifically, embodiments relate to a method for fabricating a CMOS image sensor, capable of improving reliability and yield of devices via a rework process to prevent corrosion of metal pads.

Embodiments relate to a method for fabricating a CMOS image sensor, capable of preventing pads from being scrapped, via a rework process to remove regions, wherein pads corrode, formed in the process of fabricating CMOS image sensors.

Embodiments relate to a method for fabricating a CMOS image sensor, capable of preventing pads from being scrapped, via a rework process to remove flower-like corrosion caused by fluorine generated in the process of fabricating CMOS image sensors.

Embodiments relate to a method for fabricating a CMOS image sensor, capable of preventing pads from being scrapped via a rework process to remove appearance defects of the pads generated in the process of fabricating CMOS image sensors.

Embodiments relate to a method for fabricating a semiconductor device, including: developing a semiconductor substrate provided with metal pads with tetramethylammonium hydroxide (TMAH), to etch the metal pads.

Embodiments relate to a method for fabricating a CMOS image sensor, including: forming a metal pad over a pad region of a substrate including an active region and the pad region; forming a protective film over the entire surface of the substrate including the metal pad, and selectively removing the protective film such that the surface of the metal pad is exposed, to form a metal pad opening; wet cleaning the metal pad exposed by the metal pad opening; forming a first planarized layer over the entire surface of the semiconductor substrate, and sequentially forming a color array, a second planarized layer and a microlens in the active region over the first planarized layer; performing pad inspection; performing a developing process using tetramethylammonium hydroxide (TMAH) to remove fluorine, when corrosion of metal pads is observed, during the pad inspection; and performing a reworking process after the developing process using TMAH.

### DRAWINGS

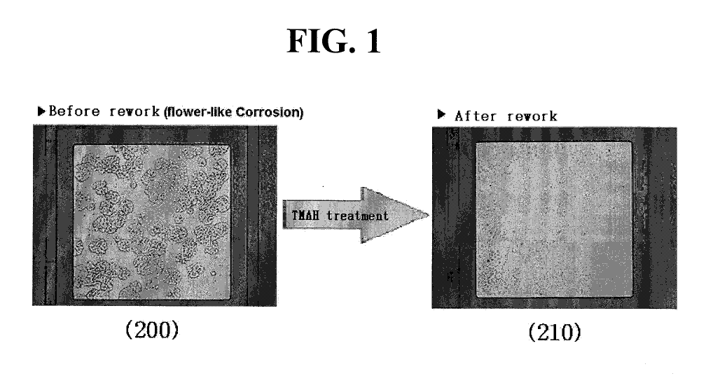

Example FIG. 1 is a view showing a method for etching Al pads according to embodiments.

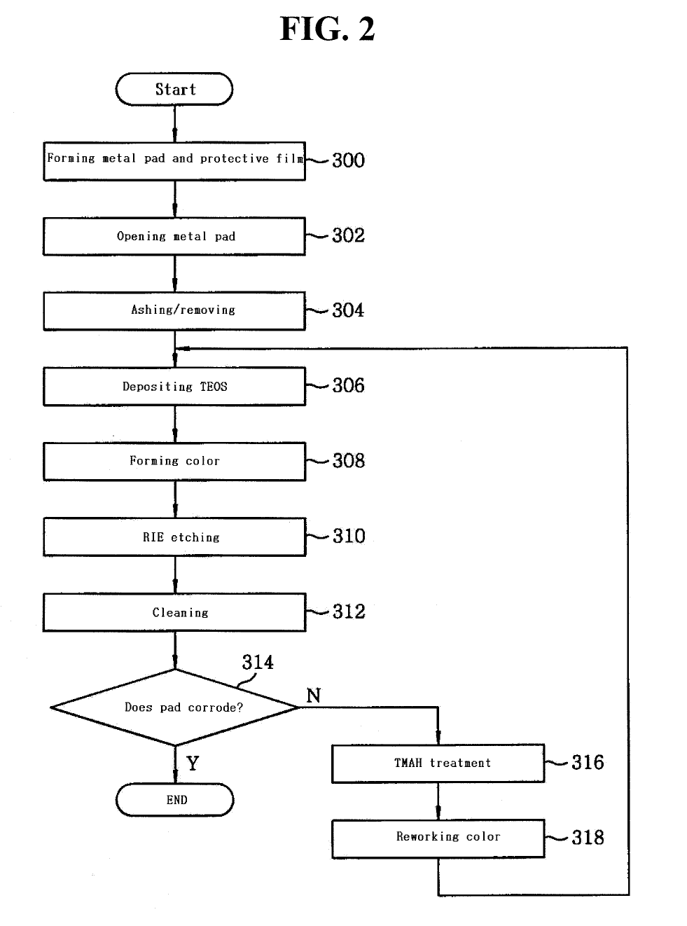

Example FIG. 2 is a flow chart illustrating a process for reworking a CMOS image sensor according to embodiments.

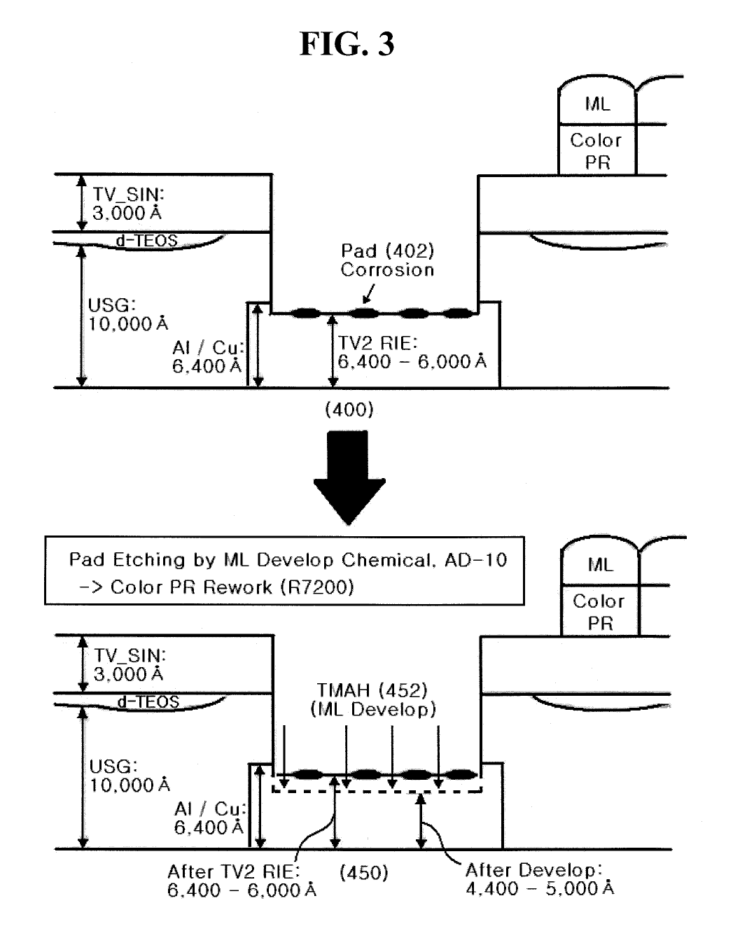

Example FIG. 3 illustrates a method for etching an Al pad according to embodiments.

### DESCRIPTION

Embodiments prevent pads from being scrapped via a re-processing step to remove corroded pad regions generated in CMOS image sensor processes. Aluminum pad corrosion is classified into galvanic corrosion, caused by a potential difference of Al/Cu, and fluorine-induced corrosion. A representative example of fluorine-induced corrosion is a flower-like corrosion generated on Al pads. When flower-like corrosion is generated, the corresponding material is disposed of in 100% of cases.

In accordance with embodiments, for materials where flower-like corrosion occurs, the surface of Al pads is etched, to remove AlₓO_{y} abnormal oxide films. This allows normal output of materials which undergo flower-like corrosion. Hereinafter, a scheme to resolve the corrosion of Al pads in the process of fabricating a CMOS image sensor will be described in detail with reference to the drawings

Example FIG. 1 is a view showing a method for etching Al pads according to embodiments. Referring to example FIG. 1, the surface of a material 200 where flower-like corrosion occurs is etched to a thickness of 500 Å to 1,500 Å. A developing process using tetramethylammonium hydroxide (hereinafter, referred to as TMAH) removes the abnormal oxide film. That is, treatment with TMAH enables removal of corroded Al pad regions, as represented by reference number 210.

A process for tetraethylortho silicate (TEOS) may be used, as a pad-protecting film, by stripping a color photoresist, and then redepositing a color photoresist (i.e., a rework process). As a result, it is possible to realize normal output of pads which were previously scrapped. After the rework process, a level of fluorine in Al pads rapidly decreases from about 27% to 3%.

Example FIG. 2 is a flow chart illustrating a process for reworking a CMOS image sensor according to embodiments. Referring to example FIG. 2, in step 300, a gate dielectric or an interlayer dielectric may be formed over a semiconductor substrate. Metal pads for respective signal lines may be formed over the gate dielectric or an interlayer dielectric. The metal pads may be made of Al or Al/Cu. A protective film may be formed over the entire surface of the dielectric including the metal pads. An oxide film or a nitride film may be used as the protective film. Then, a photosensitive film may be applied to the protective film and may be patterned by exposing and developing processes such that the top of the photosensitive film is exposed.

In step 302, the protective film may be etched using the patterned photosensitive film as a mask, to form a metal pad opening. Then, in step 304, the photosensitive film may be removed and the semiconductor substrate may be wet-cleaned. The wet-cleaning may be carried out by an ashing and an ash removal processes. In step 306, a tetraethylorthosilicate (TEOS) oxide film may be deposited as a first planarized layer. The TEOS film may be etched using a mask such that the film remains only over regions other than the metal pads.

Then, in step 308, blue, green and red color filter arrays may be sequentially formed over the TEOS oxide film. A second planarized layer may be formed, and the resulting structure is etched such that only regions not covering the metal pads remain. Microlenses may be formed over respective color filter arrays present over the second planarized layer.

Then, in step 314, the metal pads, i.e., Al pads, are inspected for corrosion. When the metal pad does not corrode, the reworking process may be finished and normal output may be performed by subsequent processes. On the other hand, when the metal pad does corrode, the metal pad opening may be treated with TMAH in step 316.

As shown in example FIG. 3, the surface of the Al pad may be etched to a thickness of 500 Å to 1,500 Å (e.g., 1,000 Å) through a developing process using TMAH, to remove flower-like corrosion on the Al pad. After TMAH etching, a thickness of the metal pad may be 4,400 Å to 5,000 Å, while the thickness of the metal pad layer shifts from 6,400 Å to 5,400-6,000 Å after RIE etching, step 310.

Then, in step 318, a color reworking process may be performed. This is a type of stripping process to remove filter arrays and may be carried out by performing a photoresist-ashing and an ash-removing processes, to remove residues present on the substrate and the metal pad opening. Subsequently, step 306 may be repeated.

TEOS may be deposited over the substrate (Step 306), color filter arrays, and a planarized layer and a microlens are sequentially formed (step 308). RIE etching (step 310) and cleaning (step 312) processes may be performed to fabricate a CMOS image sensor.

When the Al pad is etched by a developing process using TMAH, some pits may occur on the pad surface, but neither a bonding pad phenomenon nor a punch-through issue is generated. Neither problem or defect is observed upon process control module (PCM) inspection. In addition, the flower-like corrosion on the pad surface is removed, appearance defects are eliminated, and normal output can thus be realized.

As apparent from the description above, embodiments provide a method for fabricating CMOS image sensors, which is capable of preventing pads from being scrapped, via a rework process to remove a region wherein pads corrode in the process of fabrication. It is possible to realize normal output for materials, which were previously disposed of due to problems including pad corrosion, appearance defects, and bonding pad issues which may occur in the process of fabricating CMOS image sensors. A resulting advantage is that it is possible to reduce wafer disposal problems and improve product yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
providing a semiconductor substrate with at least one metal pad; and
developing the semiconductor substrate provided with a metal pad with tetramethylammonium hydroxide, to etch the at least one metal pad.

2. The method of claim 1, wherein the at least one metal pad is made of aluminum.

3. The method of claim 1, wherein the at least one metal pad is made of an alloy of aluminum and copper.

4. The method of claim 1, wherein the at least one metal pad is etched to a depth in a range of 500 Å to 1,500 Å.

5. The method of claim 1, including, after developing the semiconductor substrate, processing the semiconductor substrate to form a CMOS image sensor.

6. A method comprising:
forming at least one metal pad over a region of a substrate including an active region and a pad region;
forming a protective film over the entire surface of the substrate including the at least one metal pad, and selectively removing the protective film such that the surface of the at least one metal pad is exposed, to form at least one metal pad opening;
wet cleaning at least one metal pad exposed by the at least one metal pad opening;
forming a first planarized layer over the entire surface of the semiconductor substrate, and sequentially forming a color array, a second planarized layer and a microlens over the first planarized layer over the active region;
performing a pad inspection of the at least one metal pad; and
performing a developing process using tetramethylammonium hydroxide to remove fluorine, when corrosion of at least one metal pad is observed during the pad inspection.

7. The method of claim 6, including performing a reworking process after the developing process.

8. The method of claim 7, wherein the reworking process includes:
forming a third planarized layer over the entire surface of the substrate including the at least one metal pad opening.

9. The method of claim 8, wherein the reworking process includes:
forming a color filter array over the third planarized layer.

10. The method of claim 9, wherein the reworking process includes:
forming a fourth planarized layer over the color filter layer.

11. The method of claim 10, wherein the reworking process includes:
forming a microlens over the fourth planarized layer.

12. The method of claim 6, wherein the developing process using tetramethylammonium hydroxide is performed by developing the substrate using tetramethylammonium hydroxide to etch the at least one metal pad.

13. The method of claim 6, wherein the at least one metal pad is etched to a depth in a range between 500 Å to 1500 Å.

14. The method of claim 6, wherein the metal pad is made of aluminum.

15. The method of claim 6, wherein the metal pad is made of an alloy of aluminum and copper.

16. The method of claim 7, wherein the metal pad is made of one of aluminum and an alloy of aluminum and copper.

17. The method of claim 11, wherein the metal pad is made of aluminum.

18. The method of claim 11, wherein the metal pad is made of an alloy of aluminum and copper.

19. The method of claim 12, wherein the metal pad is made of one of aluminum and an alloy of aluminum and copper.

20. The method of claim 13, wherein the metal pad is made of one of aluminum and an alloy of aluminum and copper.
